(19) United States
(12) Patent Application Publication
(10) Pub. No.: US 2013/0320958 A1
(43) Pub. Date: Dec. 5, 2013

(54) Box wizard and the rock wizard

(71) Applicant: Bradley J. Collins, Tacoma, WA (US)

(72) Inventor: Bradley J. Collins, Tacoma, WA (US)

(21) Appl. No.: 12/928,555

(22) Filed: May 11, 2011

Related U.S. Application Data
(60) Provisional application No. 61/404,079, filed on Sep. 28, 2010.

(51) Int. Cl. G01R 19/00

(52) U.S. Cl. 324/67

(57) ABSTRACT

A template set for position of electrical boxes that is a two piece tool system comprising of
1) Template A
2) Template B

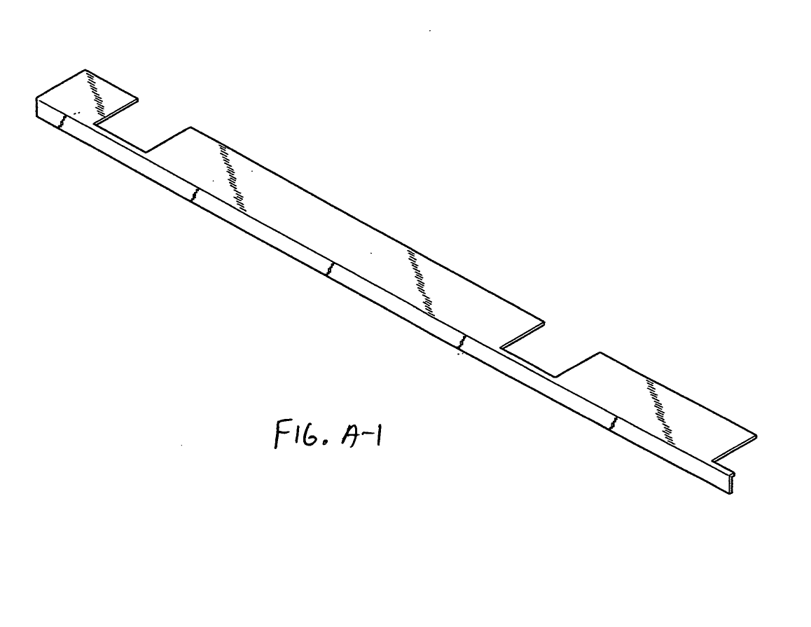

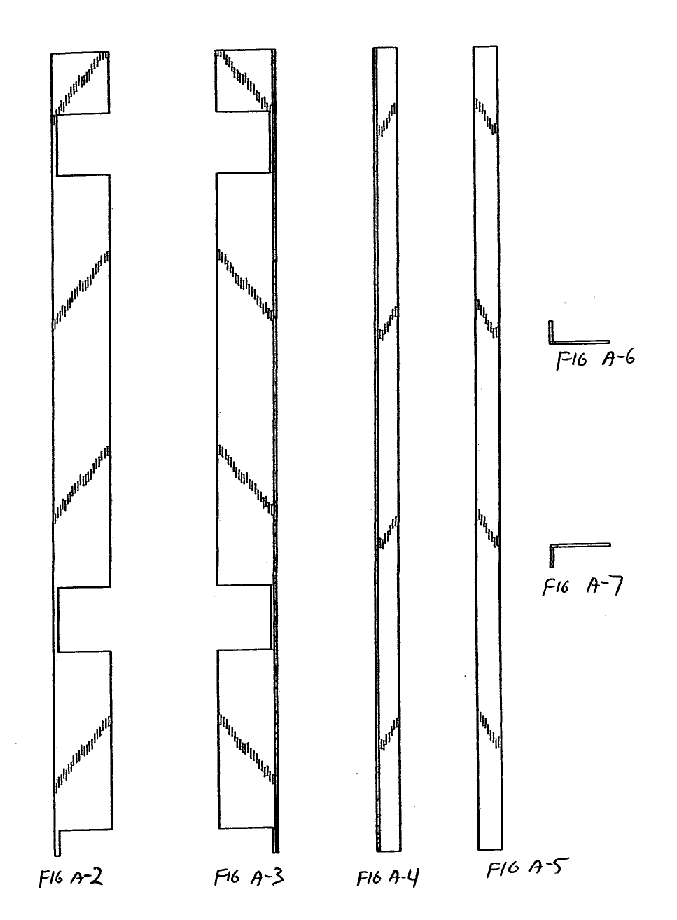

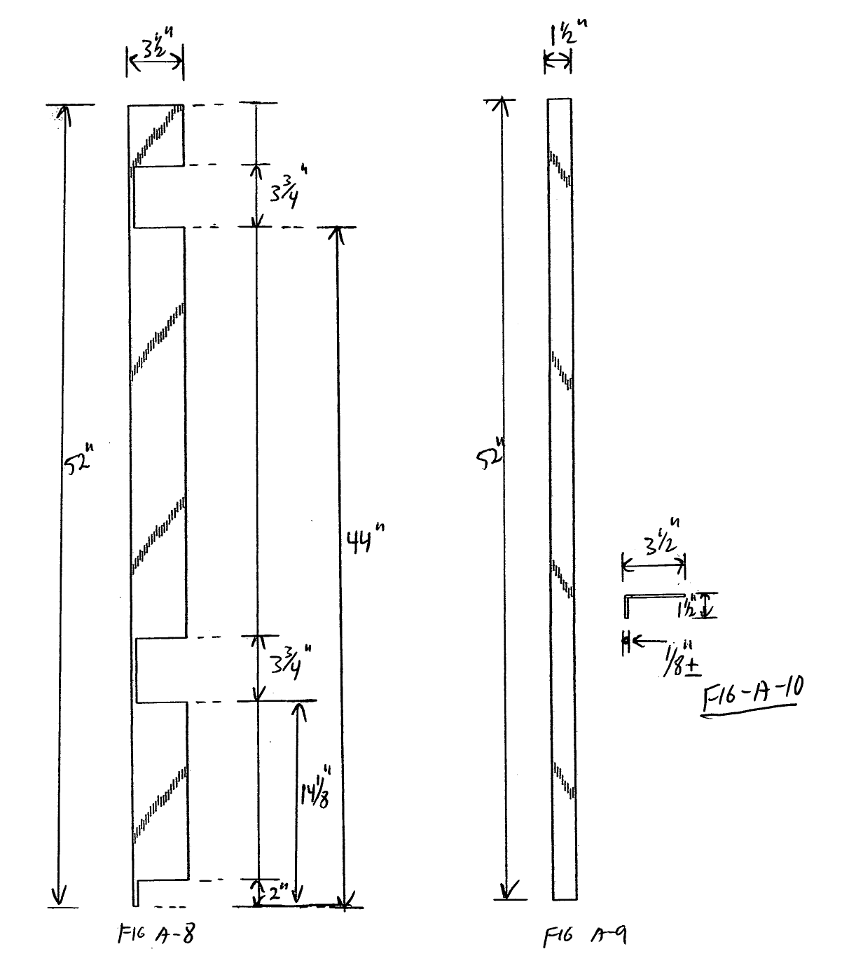

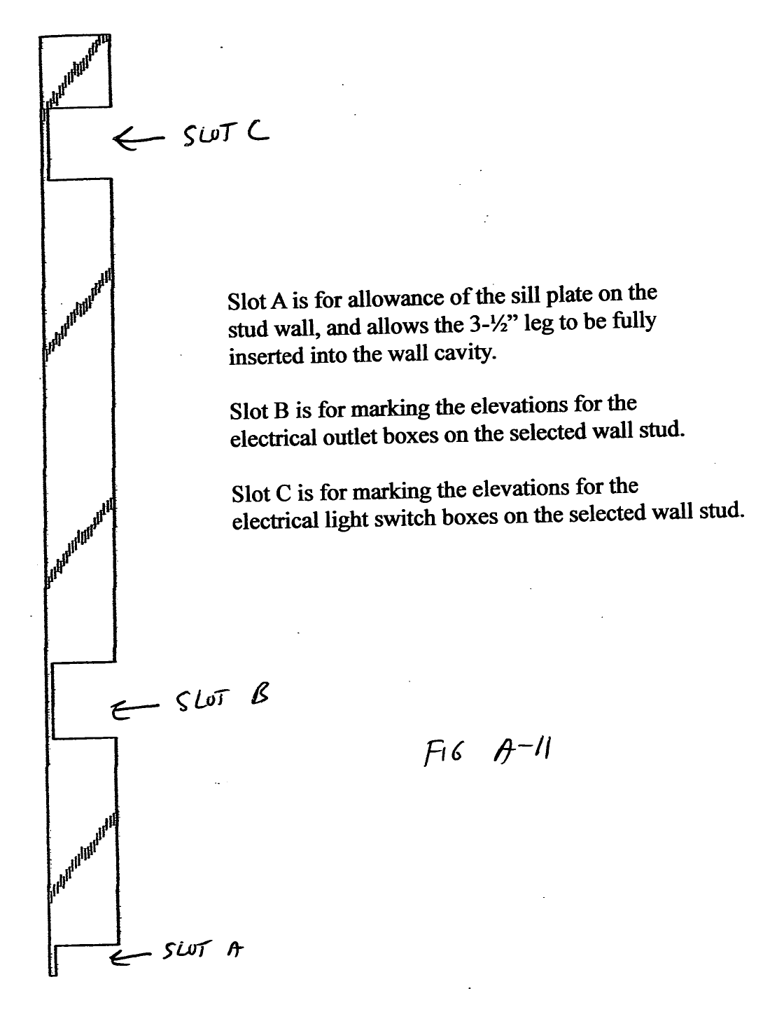

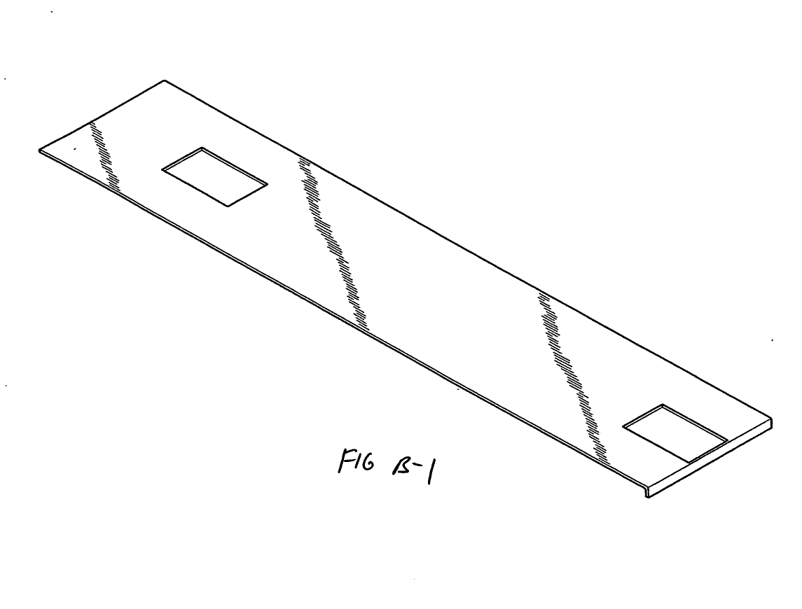

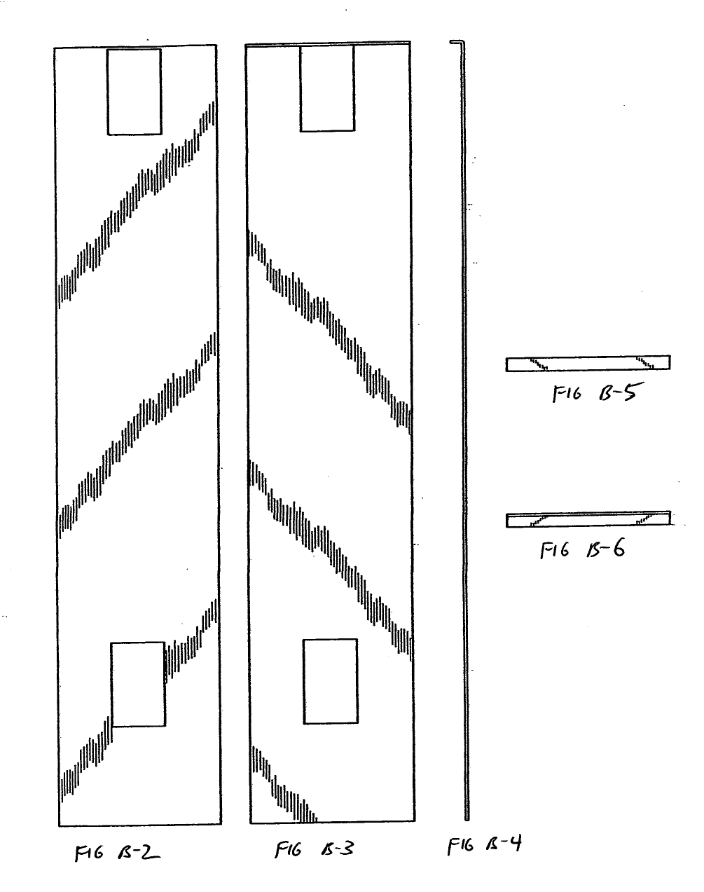

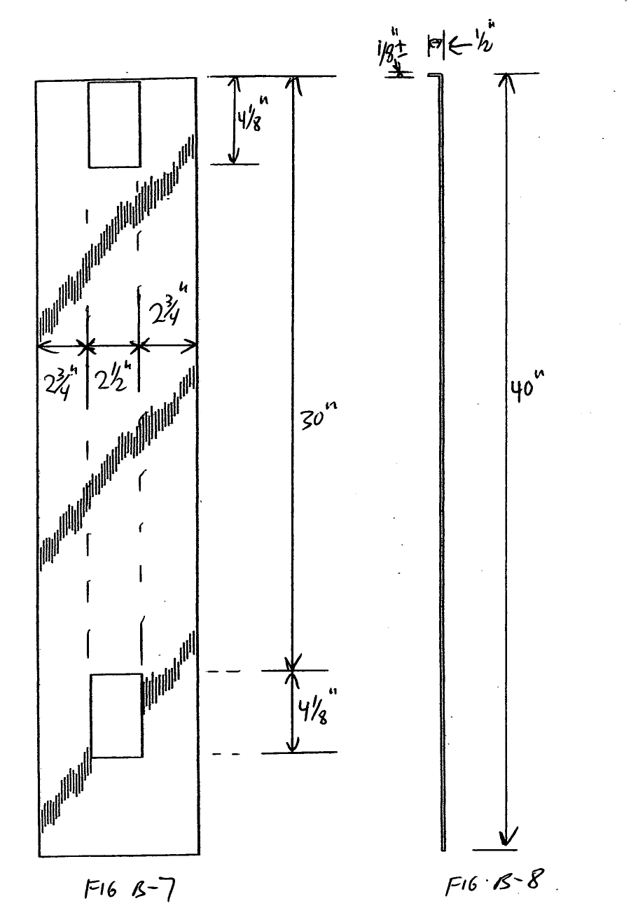

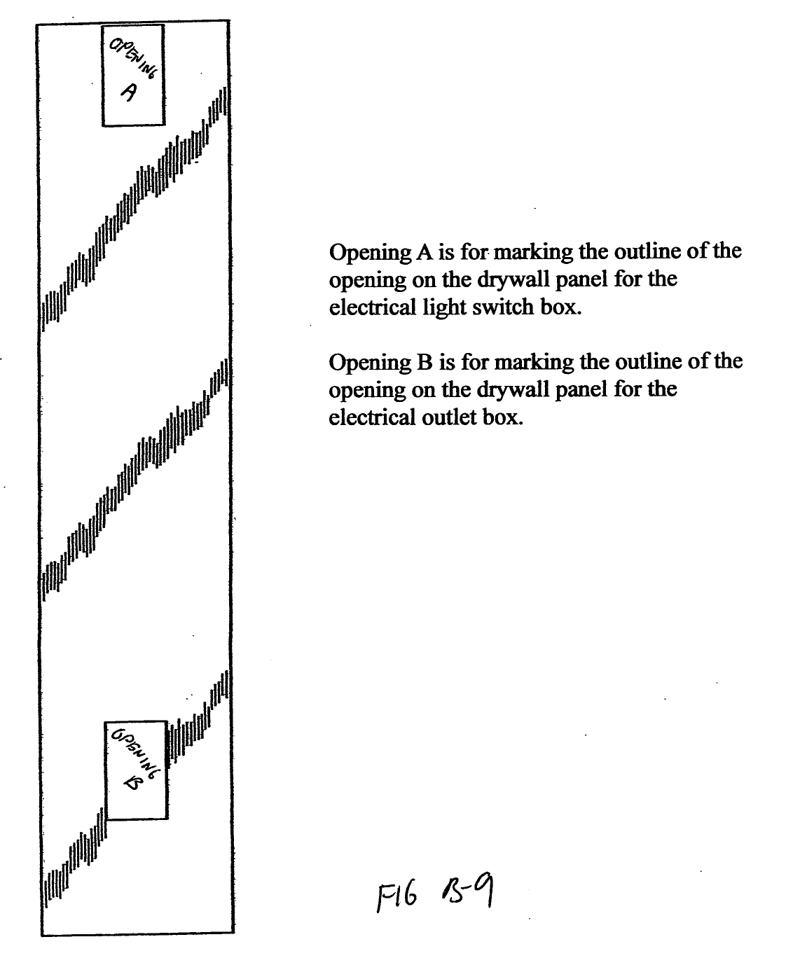

Template A is used to mark the wall studs at specific elevations for the setting of the electrical boxes, either for outlets or light switches.

Template B is then used to mark the sheetrock for the holes for the electrical boxes and switches. The result is a near perfect fit of the sheetrock over the electrical boxes every time.

### CROSS-REFERENCE TO RELATED APPLICATIONS

| | | | |
|---|---|---|---|
| 3,522,658 | August 1970 | Howell | 33/528 |
| 3,678,588 | July 1972 | Isola et al. | 33/528 |
| 3,875,669 | April 1975 | Hull | 33/528 |
| 4,228,592 | October 1980 | Badger | 33/DIG. 10 |
| 4,696,113 | September 1987 | Rice | 33/DIG. 10 |
| 5,222,303 | June 1993 | Jardine | 33/528 |
| 5,357,683 | October 1994 | Trevino | 33/528 |
| 5,615,490 | April 1997 | Burchell | 33/528 |
| 5,860,219 | January 1999 | Wilkinson | 33/528 |

### STATEMENT REGARDING FEDERALLY SPONSORED RESEARCH OR DEVELOPMENT

“Not Applicable”

### THE NAMES OF THE PARTIES TO A JOINT RESEARCH AGREEMENT

“Not Applicable”

### INCORPORATION-BY-REFERENCE OF MATERIAL SUBMITTED ON A COMPACT DISC

See compact disc

### BACKGROUND OF THE INVENTION

(1) Field of Invention

The present invention relates to templates for use in home and building construction or remodeling, specifically to, A) Set the elevations for electrical switch boxes and electrical outlet boxes and B) the coordination of the corresponding opening's in the sheet rock or other wallboard coverings.

One of the more challenging aspects of building and home construction, is the coordination of the electrical light switch and outlet boxes with the corresponding opening in the drywall or wallboard.

Sheetrock and gypsum wallboard are the most common materials used. Unfortunately, these materials are somewhat fragile and are susceptible to cracking and breaking fairly easy, so that care must be taken to ensure that the opening for the electrical boxes are correct. This necessitates that precise measurements are taken, which is time consuming and allows for errors to occur.

It is no surprise then, that various attempts to simplify and speed up the process have been patented.

2) Description of Related Art

Construction work on homes or buildings is done in phases. The electrical work, the setting of electrical boxes and pulling wire throughout the structure, is typically done weeks before the drywall workers can begin. (Insulation, plumbing, communications and the like all have to be done prior to drywall, contributing to the time lapse between the electrical and drywall phases).

Clarke, U.S. Pat. No. 4,126,941 and Hull, U.S. Pat. No. 3,875,669 are both templates or gage's that address setting the elevations of the electrical boxes, but do not address the corresponding openings in the drywall.

Elliott, U.S. Pat. No. 3,842,510,—Trevind, U.S. Pat. No. 5,357,688 and Digavero Etal, patent # US2008/0155845-A2, all address the opening in the drywall for electrical boxes but do not address the installation of the electrical boxes.

Jardine, U.S. Pat. No. 5,222,303, address both the placement of the electrical outlet boxes and the corresponding openings in the drywall, typically located 14″ above the floor. However, it does not address, without additional tools, the placement of the electrical light switch boxes or the corresponding opening in the sheet rock, which are typically located 48″ above the floor.

Wilkinson, U.S. Pat. No. 5,860,219, addresses both the setting of the electrical box locations for the outlets and switches, and also addresses the corresponding holes in the drywall. However, Wilkinson is an adjustable system. Meaning, that to mark the studs for outlet boxes, you make that adjustment in elevation by sliding the template along the wallboard square to the desired height. To mark the studs for light switch boxes, you have to re-adjust the template for that elevation.

To mark the drywall for the electrical box opening, it is the same process. A different adjustment for switch boxes than for the outlet boxes.

With each adjustment, comes the possibility of error. As drywall installers typically install one room at a time, each room containing 2 or 3 switch boxes and 5 or 6 outlet boxes. A lot of time is spent adjusting the Wilkinson template system.

My 2 piece template system eliminates all of these issues . My tool set is so simple, as to be elegant in design and functionality, with no moving parts and no adjustments. It is fast and easy to use.

### BRIEF SUMMARY OF THE INVENTION

The present invention is a 2-piece template set that minimizes the potential for error that is inherent in the prior art, while providing a fast and efficient method for installing electrical light switch and outlet boxes in the stud wall cavity and also coordinating the corresponding opening in the drywall for said electrical boxes, in a fast but reliable method every time.

Elegant in design and functionality with no moving parts and with no adjustments. It is fast and easy to use.

A single measurement taken horizontally to correctly place template “B”, reduces the possibility of error to a single measurement. The single measurement feature also saves both the electrical box installer and the drywall installer hours of time and labor on each project.

This is the first template system that attempts to “standardize” the elevations for both electrical light switch boxes and electrical outlet boxes.

### BRIEF DESCRIPTION OF THE SEVERAL VIEWS OF THE DRAWINGS

FIG. A-1, is a isometric view of Template A

FIG. A-2, is a right hand view of template A

FIG. A-3, is a left hand view of template A

FIG. A-4, is an inside view of template A

FIG. A-5, is an outside view of template A

FIG. A-6, is a top-down view of template A

FIG. A-7, is a bottom-up view of template A

FIGS. A-8, A-9 & A-10 provides exact measurements to produce template A

FIG. A-11, provides an explanation of the slots, A, B & C.

FIG. B-1, is an isometric of template B

FIG. B-2, is a outside view of template B

FIG. B-3, is a inside view of template B

FIG. B-4, is both left & right hand views of template B

FIG. B-5, is a top-down view of template B

FIG. B-6, is bottom looking up of template B

FIGS. B-7 & B-8, provide exact measurements to produce template B

FIG. B-9, provides an explanation for the opening's in template B.

### DETAILED DESCRIPTION OF THE INVENTION

What is un-obvious and unique about this template set, is that we are measuring from both the top and the bottom of the 4 ft. wide drywall panel. Sheet rock, gypsum wall board, and drywall are all manufactured to exact widths, 48 inches wide exactly. This exact manufacturing process, allows us to measure from both the top and bottom with confidence.

Essentially, template “A” measures from the bottom up to set the elevations for the electrical light switch and outlet boxes. Template “B”, measures from the top of the drywall panel downward to mark the openings for the electrical box openings.

Template “A”, is an ⅛″ thick L-Shaped tool that measures 1 ½″×3 ½″ to form the L shape and is 52″ long with 3 slots cut out of the 3 ½″ leg, at specific elevations for marking the wall stud for placement of the electrical boxes. The L-Shape fits over the wall stud, with the 3 ½″ leg inserted into the wall cavity and the 1 ½″ leg fitted tightly to the outside face of the wall stud. A pencil or marking pen is then used to mark the wall stud at the desired slot. The upper slot is for light switch boxes, the lower slot is for the outlet boxes. The bottom slot allows for the sill plate of the stud wall, which allows the 3-½″ leg free access into the wall cavity. The electric boxes are then installed between the pencil marks on the wall stud.

Because the wall stud is marked inside the wall cavity, a more accurate installation of the electrical boxes is possible. This is a significant improvement over the prior art.

Template “B”, is a ⅛″ thick flat tool measuring 8″ wide by 40″ tall, with a ½″ leg turned back at the top, to sit on top of a drywall panel. Two square opening's are cut out of the tool, at specific elevations and of exact sizes to correspond with the electric boxes.

To use template “B” to mark the drywall for the electric box opening, only one measurement is required. Measuring horizontally from the corner, or the edge of the previously installed drywall panel, to the center of the electrical box, this measurement is then transferred to the drywall panel. Template B is then moved horizontally along the drywall panel, until the center line mark on the tool lines up with the transferred mark on the drywall panel. Then a pencil or marking pen is used to mark the opening for the electrical box onto the drywall panel. The marked electrical box opening can now be cut out and the drywall panel installed for a perfect fit around the electrical box every time.

What is claimed is:

1) A 2 piece template set that establishes a standard vertical height for the installation of the electrical light switch boxes and outlet boxes on the wall studs during construction and coordinates the corresponding openings in the drywall panel utilizing a single measurement system comprised of;
template A, an elongated L-shaped tool with notches cut out of one leg for marking the wall studs inside the wall cavity for accurate placement of the electrical boxes;
template B, an essentially flat tool with openings to mark the drywall panel at the appropriate locations for the electrical box openings, that hangs vertically on said drywall panel and slides horizontally along said drywall panel to the specific horizontal position that is dictated by the single measurement, from the previously installed drywall panel or the corner.

2) a single measurement tool set that accurately positions the electrical boxes at specific elevations and coordinates the corresponding openings in the drywall panels.

3) A two piece tool set with no moving parts and no adjustable pieces, that attempts to make standard, the vertical locations of the electrical light switches and electrical outlets throughout an entire building or home.
